(19) United States
(12) Patent Application Publication
(10) Pub. No.: US 2024/0268063 A1
(43) Pub. Date: Aug. 8, 2024

(54) CHASSIS FOR USE IN FANLESS AND FAN-COOLED DEVICES

(71) Applicant: Rakuten Symphony UK Ltd, Surrey (GB)

(72) Inventor: Gerard MacManus, Surrey (GB)

(73) Assignee: Rakuten Symphony UK Ltd, Surrey (GB)

(21) Appl. No.: 18/021,473

(22) PCT Filed: Jul. 29, 2022
(86) PCT No.: PCT/US2022/038791

§ 371 Date: Feb. 15, 2023

Related U.S. Application Data
(60) Provisional application No. 63/345,783, filed on May 25, 2022.

(51) Int. Cl. H05K 7/20

(52) U.S. Cl. CPC H05K 7/20172; H05K 7/20418

(57) ABSTRACT

A chassis is provided for supporting electronic device circuitry. The chassis includes a mounting surface on a first side of the chassis and a cooling surface on a second side of the chassis opposite the mounting surface. The cooling surface has a plurality of fin fixation connectors for fixing cooling fins to the cooling surface. The chassis also has at least one fan connector for fixing a fan assembly at or adjacent the cooling surface. Also provided is a chassis system for electronic device circuitry. Such a system can be used in a fanless configuration and a fan-cooled configuration. In addition to the chassis, the system includes a first set of fins having a first length and a first depth and a second set of fins having a second length and a second depth smaller than the first depth. The system also includes a fan assembly.

### FIELD OF THE INVENTION

This application relates to a chassis for thermal management in a wireless communication device having heatsinks for dissipating heat. In particular, this application relates to such a chassis that can be used in both fanless and fan-cooled devices, as well as a conversion between fanless and fan-cooled products.

### BACKGROUND

Various electronic devices may comprise various circuit boards and other electronic components mounted on cooling structures. Such cooling structures may include a chassis with a mounting surface on one side and various cooling features integrated into the chassis. Such cooling features may include cooling fins on a side of the chassis opposite the mounting surface, such that the cooling fins can draw heat away from a circuit board or other electronic components mounted on the mounting surface.

As an example, wireless communication devices such as mMIMO (massive Multiple-Input Multiple-Output) devices may be cooled using a chassis having a mounting surface on one side and may be cooled by either a fan or a fanless structure. This may include a fanless conductor, such as a finned heatsink, or a combination of fanless and fan-cooled structures, depending on the size of the device and/or power consumption requirements. Devices are typically designed and constructed to be either fanless or fan-cooled.

In some such electronic devices, circuit boards may be installed on a mounting surface of a chassis, the chassis including a heat sink, such as a finned heat sink. The circuit boards may then be enclosed in a housing or otherwise configured such that most or all heat generated by the circuit boards and related electronics must be dissipated by way of the heat sink.

Sometimes, products are required to be fanless, while in other cases there is a need for a smaller unit in some markets. Smaller units typically require fan-cooling, particularly if the cooling components are expected to be partially or mostly enclosed. In some cases, the same chassis should be usable across a wide range of temperature requirements and for use in both fanless and fan-cooled devices.

There is a need for improved devices for addressing heat management. There is a need for such improved devices that can be convertible between fanless and fan-cooled devices.

### SUMMARY

A chassis is provided for supporting electronic device circuitry. The chassis includes a mounting surface on a first side of the chassis and a cooling surface on a second side of the chassis opposite the mounting surface. The cooling surface has a plurality of fin fixation connectors for fixing cooling fins to the cooling surface. The chassis also has at least one fan connector for fixing a fan assembly at or adjacent the cooling surface.

In some embodiments, the chassis includes a selected plurality of fins, where the selected plurality of fins is one of a plurality of fanless fins or a plurality of fan-cooled fins. In some such embodiments, a fan assembly is provided and fixed to the at least one fan connector, and the selected plurality of fins is the plurality of fan-cooled fins.

In some embodiments, the fan assembly is a fan tray having a plurality of fans. When fixed to the at least one fan connector, the plurality of fans are then arrayed across a width of the chassis.

In some embodiments, each fin of the plurality of fanless fins has a first length and a first depth, and each fin of the plurality of fan-cooled fins has a second length and a second depth, and the first length is the same as the second length and the first depth is larger than the second depth.

In some embodiments, each of the fin fixation connectors runs from a first end of the cooling surface to a second end of the cooling surface, and the fan connector is adjacent the first end of the cooling surface.

In some embodiments, each of the fin fixation connectors is a groove. In some such embodiments, during assembly each of the selected plurality of fins is permanently bonded to the corresponding grooves. In other embodiments, during assembly, fins of the selected plurality of fins are permanently bonded to every other groove.

In some embodiments, the chassis includes an integrated mounting structure, and the integrated mounting structure extends from the cooling surface by at least the first depth.

In some such embodiments, the chassis includes a rear baffle, and when the selected plurality of fins is the plurality of fan-cooled fins, the rear baffle is retained on the integrated mounting structure and the fan assembly is fixed to the at least one fan connector.

In some embodiments, each of the fin fixation connectors is an engagement pin.

In some embodiments, the fin fixation connectors work in concert with retaining strips for retaining the cooling fins relative to the cooling surface.

Also provided is a chassis system for electronic device circuitry, where the chassis system can be used in a fanless configuration and a fan-cooled configuration.

Such a system includes a chassis for the electronic device circuitry having a mounting surface on a first side of the chassis for mounting electronics and a cooling surface on a second side of the chassis opposite the mounting surface. The cooling side has a plurality of fin fixation connectors for fixing cooling fins to the cooling surface. The chassis includes at least one fan connector at or adjacent the cooling surface.

The system further includes a first plurality, or set, of fins having a first length and a first depth and a second plurality, or set, of fins having a second length and a second depth smaller than the first depth. The system also includes a fan assembly.

When in a first, fanless, configuration, fins of the first plurality of fins are fixed to the plurality of fin fixation connectors and the fan assembly is not attached to the chassis. In a second, fan-cooled, configuration, fins of the second plurality of fins are fixed to the plurality of fin fixation connectors and the fan assembly is fixed to the at least one fan connector.

In some such embodiments, the first length is the same as the second length, and is substantially similar to a length of the cooling surface. The fin fixation connectors then run along the length of the cooling surface, and the at least one fan connector is adjacent a first end of the length of the cooling surface.

In some such embodiments, each fin fixation connector is a groove in the cooling surface.

In some such embodiments, during assembly, one of the first plurality of fins and the second plurality of fins is selected, and the selected plurality of fins is permanently bonded to the corresponding grooves.

In some embodiments, the chassis for the electronic device circuitry includes an integrated mounting structure extending from the cooling surface by at least the first depth. The chassis system then further includes a rear baffle, and the rear baffle is retained on the integrated mounting structure in the second configuration.

In some embodiments, the plurality of fin fixation connectors are engagement pins.

In some embodiments, the fin fixation connectors work in concert with retaining strips for retaining the selected plurality of fins relative to the cooling surface.

### BRIEF DESCRIPTION OF THE DRAWINGS

FIG. 1 is a device in accordance with this disclosure.

FIG. 2 is the device of FIG. 1 mounted on a post.

FIG. 3 is a top view of the device of FIG. 1.

FIG. 4 is a front perspective view of a device in accordance with this disclosure in a first configuration.

FIG. 5 is a top view of the device of FIG. 4 in the first configuration.

FIG. 6 is a back perspective view of the device of FIG. 4 in the first configuration with a housing removed.

FIG. 7 is a front perspective view of the device of FIG. 4 in a second configuration.

FIG. 8 is a top view of the device of FIG. 4 in the second configuration.

FIG. 9 is an exploded view of the device of FIG. 4 in the second configuration.

FIG. 10 is a front perspective view of the device of FIG. 4 with fins removed.

FIG. 11 is a back perspective view of the device of FIG. 4 with fins removed.

### DETAILED DESCRIPTION OF THE PREFERRED EMBODIMENTS

The description of illustrative embodiments according to principles of the present invention is intended to be read in connection with the accompanying drawings, which are to be considered part of the entire written description. In the description of embodiments of the invention disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” and similar refer to a relationship wherein structures are secured or attached to one another either directly or indirectly through intervening structures, as well as both movable or rigid attachments or relationships, unless expressly described otherwise. Moreover, the features and benefits of the invention are illustrated by reference to the exemplified embodiments. Accordingly, the invention expressly should not be limited to such exemplary embodiments illustrating some possible non-limiting combination of features that may exist alone or in other combinations of features; the scope of the invention being defined by the claims appended hereto.

This disclosure describes the best mode or modes of practicing the invention as presently contemplated. This description is not intended to be understood in a limiting sense, but provides an example of the invention presented solely for illustrative purposes by reference to the accompanying drawings to advise one of ordinary skill in the art of the advantages and construction of the invention. In the various views of the drawings, like reference characters designate like or similar parts.

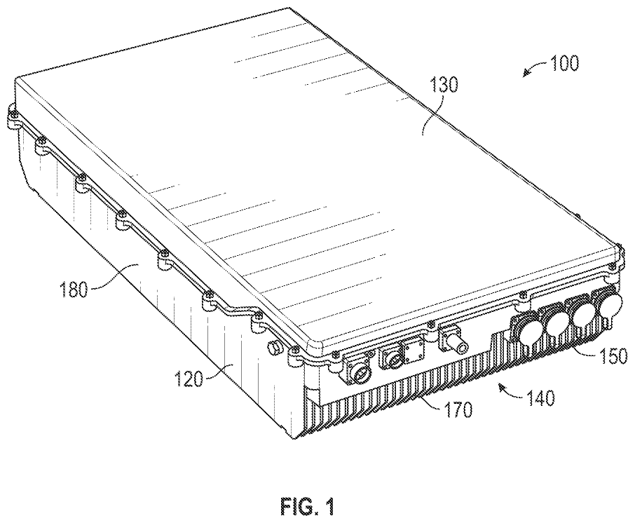

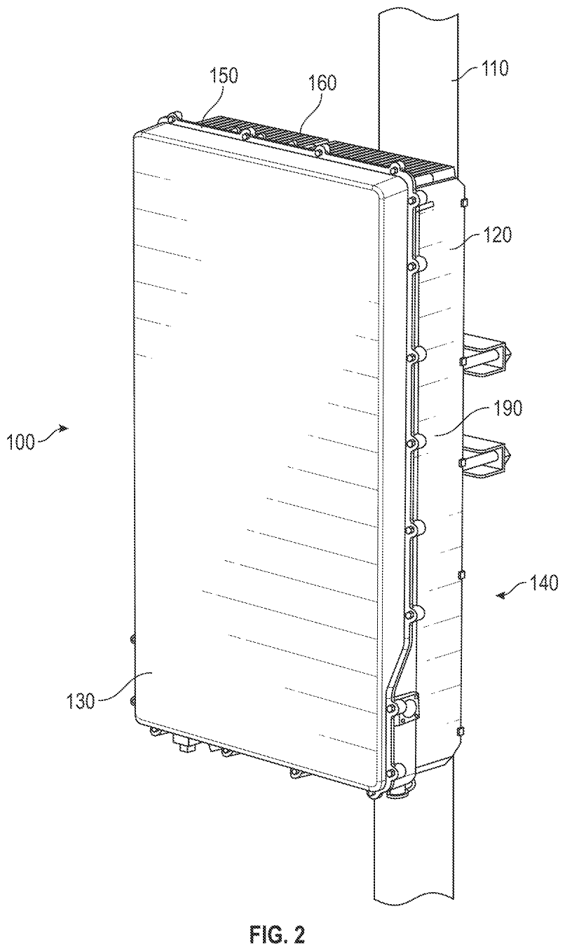

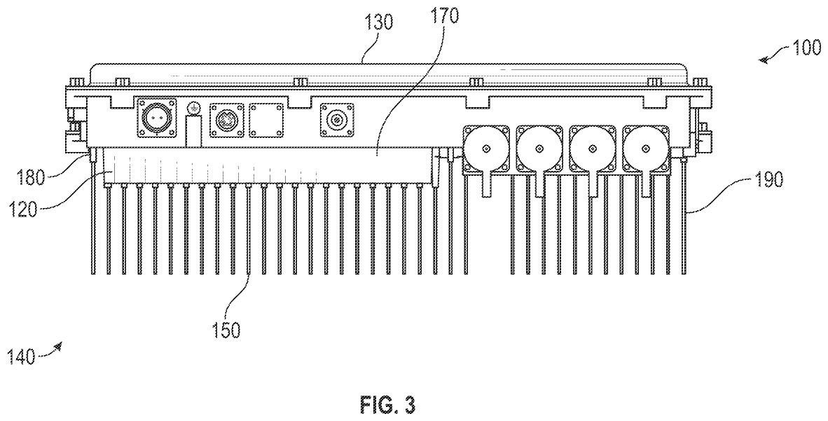

FIG. 1 is a device 100 in accordance with this disclosure. FIG. 2 is the device 100 of FIG. 1 mounted on a post 110. FIG. 3 is a top view of the device 100 of FIG. 1.

As shown, the device 100 may include a chassis 120 supporting various electronics, such as an mMIMO (massive Multiple-Input Multiple-Output) device with significant cooling requirements. The electronics may be installed in a housing 130 installed on the chassis 120. As such, the housing 130 may enclose a mounting surface supporting various circuit boards and other electronic devices that require cooling.

Opposite the housing 130, the chassis 120 may provide a cooling heatsink 140, which may be, in a first configuration, a fanless structure comprising a large number of fins 150. The fins 150, along with portions of the chassis 130 itself, are typically formed from a conductive material and thereby draw heat away from the housing 130. Accordingly, the chassis 120 typically has a mounting surface on a first side, and the fins 150 extend from the chassis on a second side opposite the circuit board mounting surface.

As discussed in more detail below, the cooling heatsink 140 may be a fan-cooled structure in a second configuration. In such a configuration, the fins 150 provided may be smaller, and a fan tray and rear baffle may be provided as well.

As shown in FIG. 2, during use, the device 100 may be installed on a post 110, such that at least some of the fins 150 are located adjacent the post. As such, the chassis 120 may be designed such that as much heat as possible can be removed from the fins at the top 160, bottom 170, and sides 180, 190 of the device 100. Typically, such post 110 mounted implementations would utilize the device 100 in the fanless configuration shown. Fan-based configurations may then be used in implementations requiring smaller units or installation in more enclosed locations.

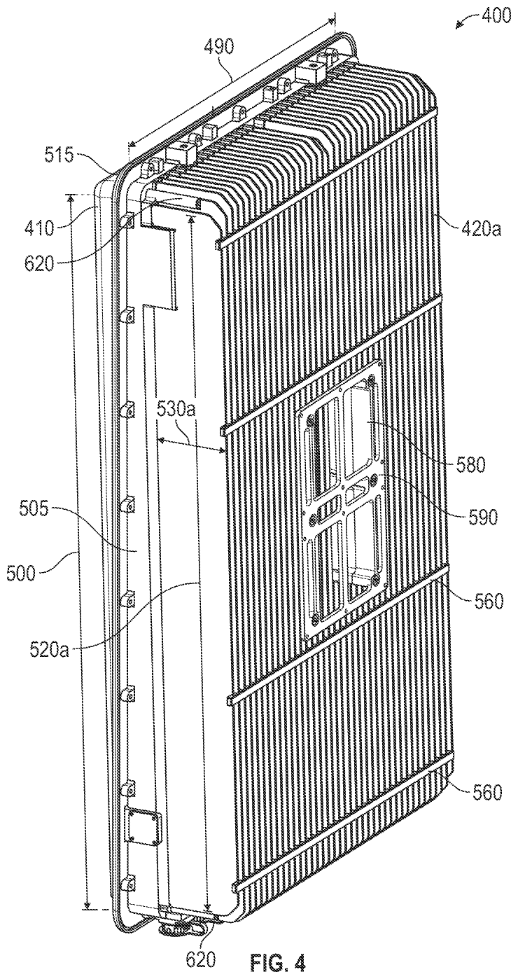

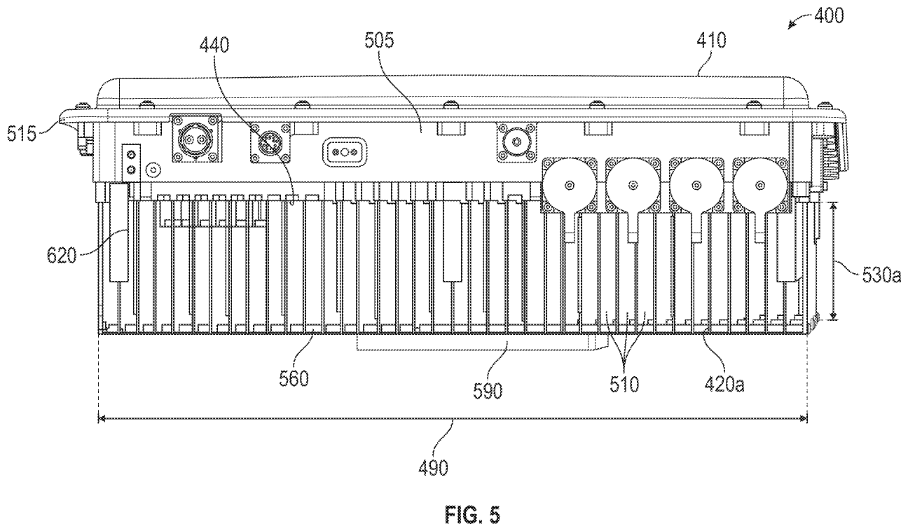

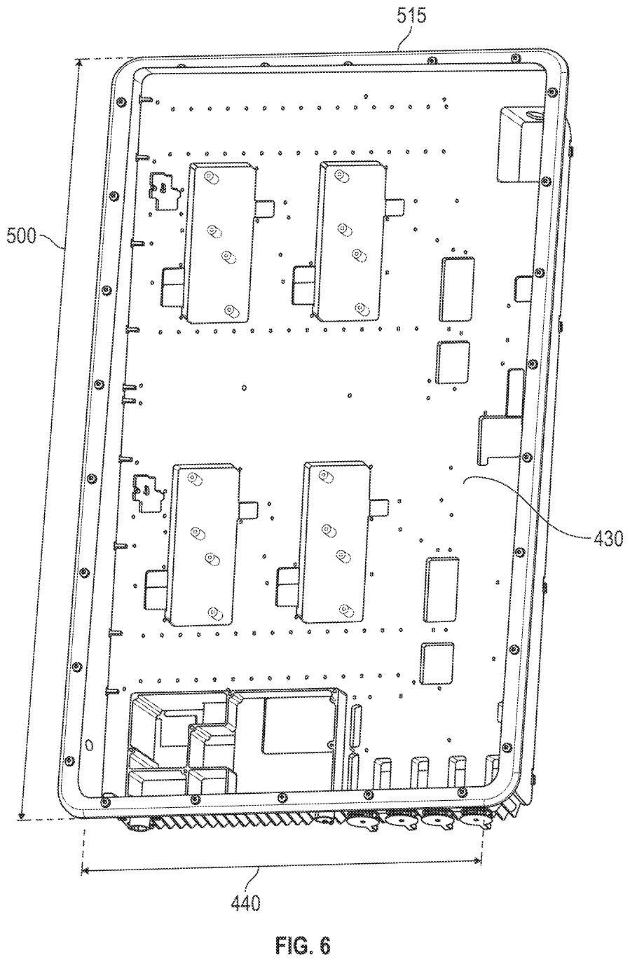

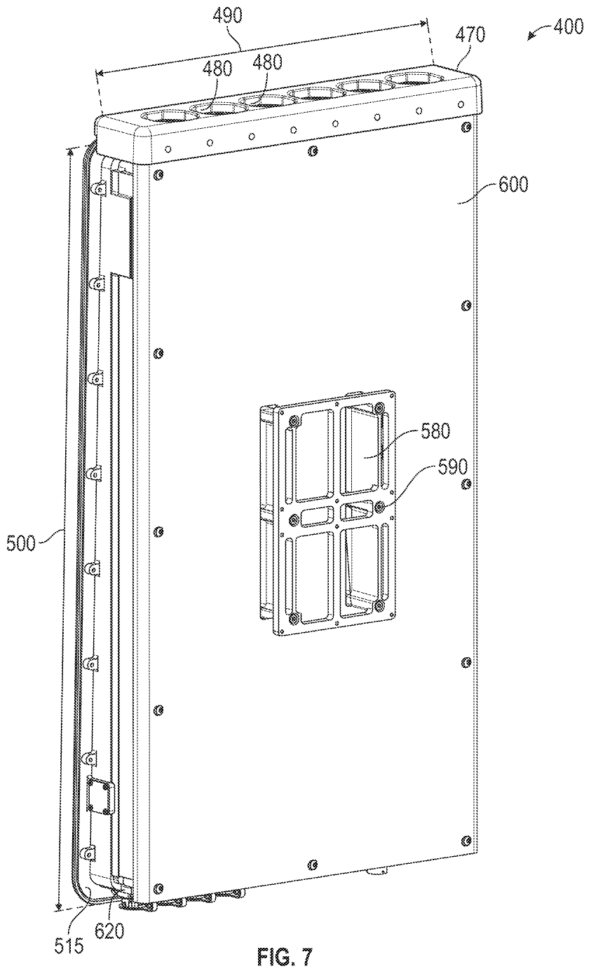

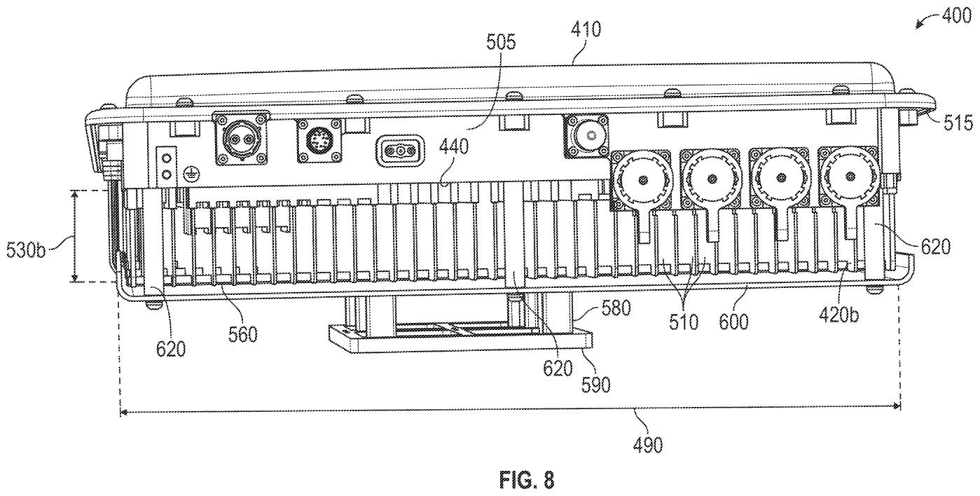

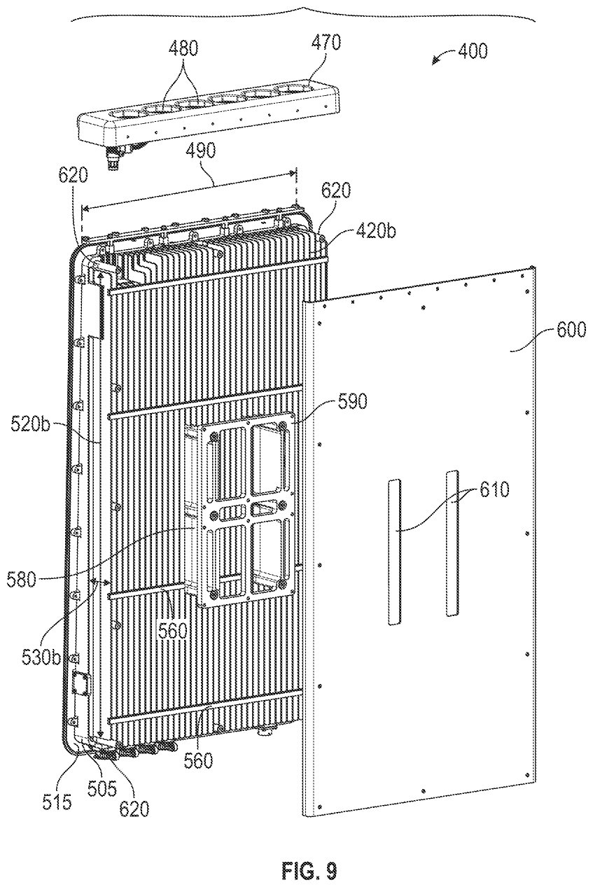

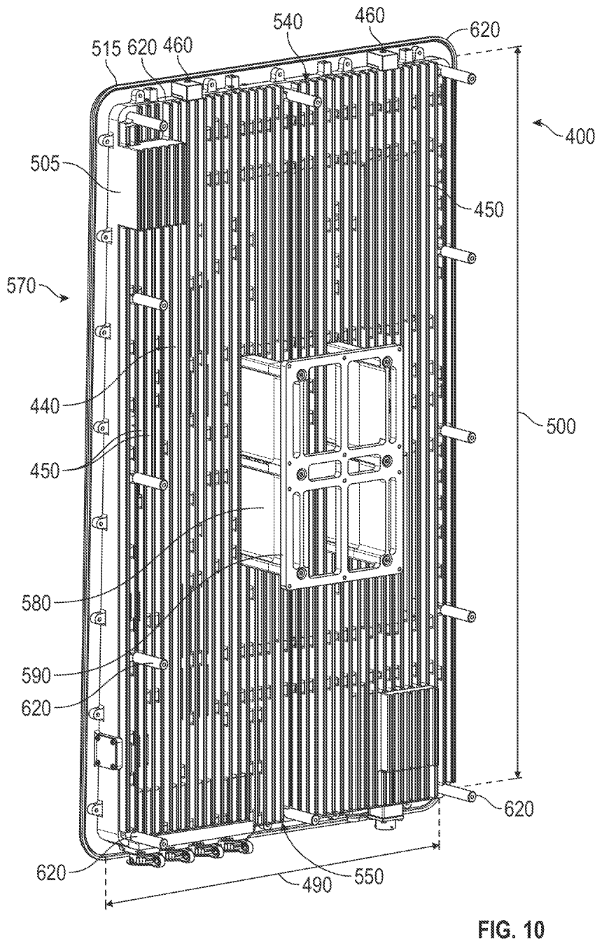

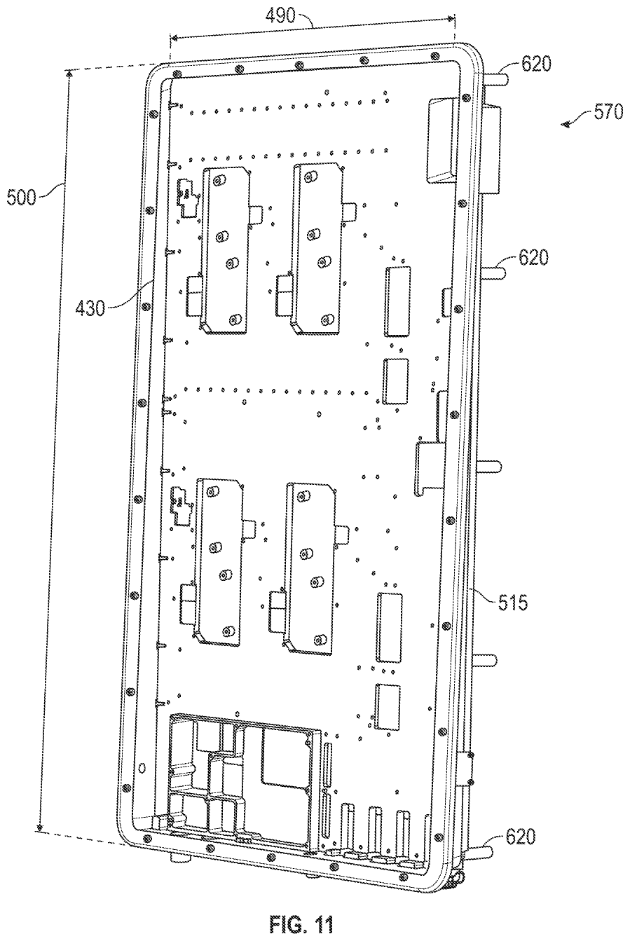

FIG. 4 is a front perspective view of a device 400 in accordance with this disclosure in a first configuration. FIG. 5 is a top view of the device 400 of FIG. 4 in the first configuration. FIG. 6 is a back perspective view of the device 400 of FIG. 4 in the first configuration with a housing 410 removed. FIG. 7 is a front perspective view of the device 400 of FIG. 4 in a second configuration. FIG. 8 is a top view of the device 400 of FIG. 4 in the second configuration. FIG. 9 is an exploded view of the device 400 of FIG. 4 in the second configuration. FIG. 10 is a front perspective view of the device 400 of FIG. 4 with fins 420a, b removed. FIG. 11 is a back perspective view of the device 400 of FIG. 4 with fins 420a, b removed.

As shown, the device 400 is a chassis for electronic device circuitry. Such circuitry is typically mounted on a mounting surface 430 of the chassis 400 located within a housing 410. During use, the housing 410 is typically in place in all configurations, as shown in FIG. 4. The mounting surface 430 is then exposed by removing the housing 410.

The chassis 400 therefore comprises a mounting surface 430 on a first side of the chassis and a cooling surface 440 on a second side of the chassis opposite the mounting surface. The cooling surface 440, most clearly visible in FIG. 10, has a plurality of fin fixation connectors 450 for fixing cooling fins 420a, b to the cooling surface.

The chassis 400 further includes at least one fan connector 460 for fixing a fan assembly at or adjacent the cooling surface.

The chassis then includes, or is paired with, a selected plurality of fins 420a, b. The selected plurality of fins may be a plurality of fanless fins 420a, or fins designed for use in a fanless configuration. Alternatively, the selected plurality of fins may be a plurality of fan-cooled fins 420b, or fins designed for use in a fan-cooled configuration.

When the fins 420a, b are fixed to the cooling surface 440, they typically run in parallel to each other along a length 500 of the chassis 400. The fins 420a, b are then distributed across a width 490 of the cooling surface 440. Such distribution may result in fins 420a, b evenly spaced across the width, and such fins may be fixed in various configurations based on the cooling requirements of the electronic device circuitry fixed to the mounting surface 430. Accordingly, fins 420a, b may be fixed to each fin fixation connector 450 available, or they may instead be fixed to every other fin fixation connector if less cooling is required.

Similarly, the fins 420a, b need not be evenly arrayed in every configuration. In some configurations, for example, cooling requirements may be higher in specific locations within the mounting surface 430, and fins 420a, b at every available fin fixation connector 450 directly opposite the specific locations but less frequently elsewhere.

Because the fins 420a, b are mounted in parallel, any such configuration results in air channels 510 between the fins. Such air channels 510 allow for heat to be removed from the adjacent fins 420a, b by convection.

FIGS. 4-6 show the chassis 400 in a fanless configuration, and as such, the fanless fins 420a are shown. In contrast, FIGS. 7-9 show the chassis 400 in a fan-cooled configuration, so the fan-cooled fins 420b are shown. Typically, as shown in FIGS. 7-9, when in the fan-cooled configuration, the chassis 400 includes a fan assembly 470 fixed to the fan connectors 460. The fan assembly 470 is then fixed adjacent the cooling surface 440.

The fan assembly 470 typically includes a plurality of fans 480 which may be arranged in an array. Accordingly, the chassis may have a width 490, and the fans 480 of the fan assembly 470 may be arrayed across the width 490 of the chassis. Accordingly, the fans 480 may blow cooling air through the air channels 510 between the fins 420b, thereby increasing convention-based heat transfer to the air.

When comparing the fanless fins 420a shown in FIGS. 4-5 and the fan-cooled fins 420b shown in FIGS. 8 and 9, it is noted that the fins are sized different. Accordingly, each fin of the plurality of fanless fins 420a has a first length 520a and a first depth 530a. Similarly, each fin of the plurality of fan-cooled fins 420b has a second length 520b and a second depth 530b.

Typically, the first length 520a is the same as the second length 520b, and is substantially similar to the length 500 of the chassis 400, as each fin 420a, b typically runs the length of the chassis in each configuration. However, the first depth 430a is typically larger than the second depth 430b. Accordingly, the air-cooled fins 420b allow for a more compact device 400 by providing smaller fins.

It will be understood that when lengths 500, 520a, 520b are referred to herein as the same or substantially similar, it will be understood that small variations may be possible due to the specific configuration being utilized. For example, in the embodiments shown, fixation points 620 for a rear baffle 600, both discussed in more detail below, are provided at corners of the device adjacent the fins 420a, b. As such, specific fins 420a, b, in this case the first and last fins, may have a shorter length in order to accommodate such fixation points 620. However, despite this small difference, these lengths are considered substantially similar.

Similarly, the chassis 400 may be provided with a heatsink section 505 and a lip 515 extending laterally past an edge of the heatsink section. As such, the lengths 520a, 520b of the fins 420a, b typically correspond to the length 500 of the heatsink section. However, these small differences, if present, would still result in lengths considered substantially similar.

The fin fixation connectors 450 can take several different forms. In the embodiment shown, they typically run from a first end 540 of the cooling surface 440 to a second end 550 of the cooling surface, thereby supporting whichever fin 420a, b is fixed to the corresponding connector 450 along its length 520a, b. The fan connectors 460 is then adjacent the first end 540 of the cooling surface 440. In this way, when in the fan-cooled configuration, the fan-cooled fins 420b are fixed to the corresponding connectors 450 in parallel to each other, thereby forming the air channels 510. The fan assembly 470, such as a fan tray, is then fixed to the fan connectors 460 adjacent the first end 540, thereby blowing air through the air channels 510.

As shown, the fin fixation connectors 450 may each be, or may each include, a groove for retaining a fin 420a, b. During assembly, each of the selected plurality of fins 420a, b may then be permanently bonded to the corresponding groove 450. Such grooves may be integrated into the cooling surface 440 itself, or may be integrated into extensions extending from the same. As noted above, the number of fins utilized across the cooling surface 440, or at specified locations of the cooling surface 440, may depend on the cooling requirements of the circuitry mounted on the mounting surface 430. As such, in some embodiments, during assembly, fins of the selected plurality 420a, b may be permanently bonded to every other groove 450, instead of each groove.

In some embodiments, the fin fixation connectors are engagement pins for engaging the fins. In some embodiments, the fin fixation connectors 450 of either type work in concert with retaining strips 560 for retaining the cooling fins 420a, b of the selected plurality of fins to the cooling surface 440.

Typically, the fin fixation connectors 450 are formed from a material that conducts heat, and may be integrated into a foundation structure 570 of the chassis. This foundation structure 570 then may be formed as one piece and may be, for example, a cast metal structure. Similarly, the fins 420a, b themselves may be formed of various materials and may be, for example, pressed or bonded. The fins 420a, b may be, for example, plate material, such as copper alloy, aluminum alloy, or polymer, or they may be 2 phase fins with integrated cooling mechanisms. In some embodiments, the fan-cooled fins 420b may be formed in a different manner or from different materials than the fanless fins 420a. Accordingly, the fins may be manufactured with material efficiencies, functionalities, or cost efficiencies tailored to their expected usages.

It will be understood that references to the chassis 400 herein may refer to either the chassis as assembled in the context of an implementation or the foundation structure 570 to be integrated into an assembly.

In some embodiments, as shown, the chassis 400 may be provided with an integrated mounting structure 580. Accordingly, when the foundation structure 570 is formed, the mounting structure 580 may be included as a single piece. This allows for the device to be mounted in a variety of ways, including to a post 110 as shown in FIG. 2. The mounting structure 580 then protects the fins 420a, b from contact with whatever surface or object the device 400 is to be mounted to.

The integrated mounting structure 580 therefore extends from the cooling surface 440 by at least the first depth 430a. As such, the mounting structure 580 can be used in either configuration with either set of fins 420a, b. The mounting structure 580 may further include a cap 590 which may include mounting apertures for fixing to a variety of external surfaces or objects. In the embodiment shown, the mounting structure 580 is integrated into the foundation structure 570, but the cap 590 is removable.

During use, when the air-cooled fins 420b are utilized in an air-cooled configuration, the chassis 400 may be further provided with a rear baffle 600. Such a rear baffle 600 may be fixed to the chassis 400 and used as a rear surface for the complete device. As such, the rear baffle may be provided with slots 610 for accommodating the mounting structure 480, such that mounting structure extends through the baffle for mounting an enclosed device 400 on an external surface or object.

The rear baffle 600 may be further fixed to the chassis at various fixation points 620, such that the rear baffle largely encloses the cooling fins 420a, b while along air to flow through the air channels 510. Accordingly, when in the fan-cooled configuration, the fan-cooled fins 420b are fixed between the cooling surface 440 and the rear baffle 600, and the air channels 510 are open at both ends. The fan assembly 470 is then fixed to the first end 540, thereby blowing air through the air channels 510 such that the air vents at the second end 550.

In some embodiments, where the integrated mounting structure 580 is provided, fins 420a, b are interrupted by the structure. Accordingly, some fins 420a, b may stop at one end of the structure and resume at a second end of the structure, such that the structure is empty, and such that two distinct fins may be provided at different sections of a single fin fixation connector. Similarly, different fin fixation connectors may be provided aligned on opposite sides of the integrated mounted structure 580. In other embodiments, the fins 420a, b may pass through the structure.

Both because some fins 420a, b are interrupted by the integrated mounting structure 480 and because some other surface features may interrupt the fins at various locations, some fins may have lengths other than those discussed above. However, this does not prevent the fins 420a, b of the first plurality and the second plurality from generally having the lengths described above.

As discussed above, the foundation structure 570 of the chassis 400 described herein may be used in either a fanless configuration using fanless fins 420a or a fan-cooled configuration using fan-cooled fins 420b and a fan assembly 470. Accordingly, the chassis 400 may be provided as a system or a kit allowing for such various configurations.

The chassis system for electronic device circuitry may then include a chassis 400 foundation structure 570 having a mounting surface 430 on a first side of the chassis for mounting electronics and a cooling surface 440 on a second side of the chassis opposite the mounting surface. The cooling surface 440 includes a plurality of fin fixation connectors 450 for fixing cooling fins 420a, b to the cooling surface. The chassis 400 also includes at least one fan connector 460 at or adjacent the cooling surface 440 for fixing a fan assembly 470 to the chassis.

The system or kit then further includes a first plurality of fins 420a each having a first length 520a and a first depth 530a and a second plurality of fins 420b each having a second length 520b and a second depth 530b. The second length 520b is generally the same or substantially similar to the first length 520a, and the second depth 530b is smaller than the first depth 530a. The system or kit then also includes a fan assembly 470.

The system or kit can be assembled in at least two configurations. In a first such configuration, fins of the first plurality of fins 420a are fixed to the plurality of fin fixation connectors 450, and the fan assembly 470 is not attached to the chassis 400. In a second such configuration, fins of the second plurality of fins 420b are fixed to the plurality of fin fixation connectors 450, and the fan assembly 470 is fixed to the at least one fan connector 460.

Generally, the first length 520a and the second length 520b are substantially similar to a length 500 of the chassis 400 or the cooling surface 440. The fin fixation connectors 450 may then run along the length 500 of the cooling surface 440, and the fan connector 460 is adjacent a first end 540 of the cooling surface.

As discussed above, the fin fixation connectors 450 may take various forms, such as grooves in the cooling surface 440. Accordingly, during assembly of a chassis 400 from the system or kit described, one of the pluralities of fins 420a, b may be selected and each fin of that plurality may be bonded to a corresponding fin fixation connector 450.

The system or kit described may further include a rear baffle 600 which may be utilized in fan-cooled configurations, such as the second configuration described above. Similarly, the system or kit may include a mounting structure 580 integrated into the foundation structure 570, and in such a configuration, the rear baffle 600, when utilized, may include slots 610 for the mounting structure 580 to pass through.

Additional features may be described above with respect to the chassis 400, and may be incorporated into the system and kit described herein. Accordingly, various additional features may be utilized in various configurations.

While the present invention has been described at some length and with some particularity with respect to the several described embodiments, it is not intended that it should be limited to any such particulars or embodiments or any particular embodiment, but it is to be construed with references to the appended claims so as to provide the broadest possible interpretation of such claims in view of the prior art and, therefore, to effectively encompass the intended scope of the invention. Furthermore, the foregoing describes the invention in terms of embodiments foreseen by the inventor for which an enabling description was available, notwithstanding that insubstantial modifications of the invention, not presently foreseen, may nonetheless represent equivalents thereto.

What is claimed is:

1. A chassis for electronic device circuitry, the chassis comprising:
a mounting surface on a first side of the chassis;
a cooling surface on a second side of the chassis opposite the mounting surface, the cooling surface having a plurality of fin fixation connectors for fixing cooling fins to the cooling surface;
at least one fan connector for fixing a fan assembly at or adjacent the cooling surface.

2. The chassis of claim 1 further comprising a selected plurality of fins, wherein the selected plurality of fins is one of a plurality of fanless fins and a plurality of fan-cooled fins.

3. The chassis of claim 2 further comprising a fan assembly fixed to the at least one fan connector, and wherein the selected plurality of fins is the plurality of fan-cooled fins.

4. The chassis of claim 3 wherein the fan assembly is a fan tray comprising a plurality of fans, and wherein when fixed to the at least one fan connector, the plurality of fans are arrayed across a width of the chassis.

5. The chassis of claim 2 wherein each fin of the plurality of fanless fins has a first length and a first depth, and wherein each fin of the plurality of fan-cooled fins has a second length and a second depth, and wherein the first length is the same as the second length and the first depth is larger than the second depth.

6. The chassis of claim 5 wherein each of the fin fixation connectors runs from a first end of the cooling surface to a second end of the cooling surface, and wherein the fan connector is adjacent the first end of the cooling surface.

7. The chassis of claim 6 wherein each of the fin fixation connectors is a groove.

8. The chassis of claim 7 wherein during assembly each of the selected plurality of fins is permanently bonded to the corresponding grooves.

9. The chassis of claim 7 wherein during assembly fins of the selected plurality of fins are permanently bonded to every other groove.

10. The chassis of claim 5 further comprising an integrated mounting structure, wherein the integrated mounting structure extends from the cooling surface by at least the first depth.

11. The chassis of claim 10 further comprising a rear baffle, and wherein when the selected plurality of fins is the plurality of fan-cooled fins, the rear baffle is retained on the integrated mounting structure and the fan assembly is fixed to the at least one fan connector.

12. The chassis of claim 1, wherein each of the fin fixation connectors is an engagement pin.

13. The chassis of claim 1, wherein the fin fixation connectors work in concert with retaining strips for retaining the cooling fins relative to the cooling surface.

14. A chassis system for electronic device circuitry comprising:
a chassis for the electronic device circuitry comprising:
a mounting surface on a first side of the chassis for mounting electronics;
a cooling surface on a second side of the chassis opposite the mounting surface, the cooling side having a plurality of fin fixation connectors for fixing cooling fins to the cooling surface; and
at least one fan connector at or adjacent the cooling surface;
a first plurality of fins having a first length and a first depth;
a second plurality of fins having a second length and a second depth smaller than the first depth; and
a fan assembly,
wherein in a first configuration, fins of the first plurality of fins are fixed to the plurality of fin fixation connectors and the fan assembly is not attached to the chassis and in a second configuration, fins of the second plurality of fins are fixed to the plurality of fin fixation connectors and the fan assembly is fixed to the at least one fan connector.

15. The chassis system of claim 14 wherein the first length is the same as the second length, and wherein the first length is substantially similar to a length of the cooling surface, and wherein the fin fixation connectors run along the length of the cooling surface, and wherein the at least one fan connector is adjacent a first end of the length of the cooling surface.

16. The chassis system of claim 15 wherein each fin fixation connector is a groove in the cooling surface.

17. The chassis system of claim 16, wherein during assembly one of the first plurality of fins and the second plurality of fins is selected, and the selected plurality of fins is permanently bonded to the corresponding grooves.

18. The chassis system of claim 14 wherein the chassis for the electronic device circuitry further comprises an integrated mounting structure extending from the cooling surface by at least the first depth, the chassis system further comprising a rear baffle, and wherein the rear baffle is retained on the integrated mounting structure in the second configuration.

19. The chassis system of claim 14 wherein the plurality of fin fixation connectors are engagement pins.

20. The chassis of claim 14, wherein the fin fixation connectors work in concert with retaining strips for retaining the selected plurality of fins relative to the cooling surface.
